(19) United States
(12) Patent Application Publication
(10) Pub. No.: US 2007/0146242 A1
(43) Pub. Date: Jun. 28, 2007

(54) High resolution display for monochrome images with color highlighting

(75) Inventors: Michael E. Miller, Honeoye Falls, NY (US); Ronald S. Cok, Rochester, NY (US)

Correspondence Address: Paul A. Leipold;Patent Legal Staff, Eastman Kodak Company, 343 State Street, Rochester, NY, 14650-2201, US

(73) Assignee: Eastman Kodak Company

(21) Appl. No.: 11/315,468

(22) Filed: Dec. 22, 2005

(51) Int. Cl. G09G 3/30

(52) U.S. Cl. 345/76

(57) ABSTRACT

A flat panel display capable of presenting high resolution monochrome images in a desired first color and highlight images in at least a desired second color different from the first color, comprising a plurality of pixels each comprised of only two individually addressable differently colored sub-pixel elements, wherein the two individually addressable differently colored sub-pixel elements emit light of the desired first color when employed together, and wherein either or both of the differently colored sub-pixel elements may be employed to emit light of the desired second color. Displays in accordance with the invention may be used to provide highlight information along with high resolution monochrome images, without the expenses associated with fabrication of high resolution full-color displays.

### FIELD OF THE INVENTION

The present invention relates to display devices with the ability to present high resolution monochrome images with colored highlight information.

### BACKGROUND OF THE INVENTION

Flat-panel display devices are used for a number of applications such as general illumination light sources and information displays. Direct view information displays generally provide either high resolution monochrome images, in which each pixel is comprised of a single sub-pixel element that emits light of a single color, or lower resolution, full-color images in which each pixel is comprised of at least three sub-pixel elements, each of the light emitting elements providing a different color of light. These three or more colors of light are then integrated by the human visual system to provide the perception of a full-color display. It is known to apply other combinations of sub-pixel elements. For example, Liang et al. in US20020191130 A1 entitled “Color display utilizing combinations of four colors” discusses a full color display utilizing combinations of four colored sub-pixel elements in which color images are displayed by controlling the gray-scale of a plurality of pixels, each pixel having four colored sub-pixel elements wherein these four colored sub-pixel elements include two sub-pixel elements emitting different primary colors and two sub-pixel elements emitting colors that are complementary to the primary colors. As shown within this patent application, the resulting four subpixel elements then form a square pixel. By including more than three subpixel elements within a pixel, the number of pixels that can be formed within a flat panel display device is typically reduced further than when three subpixel elements are employed.

In modern displays, most general-purpose flat panel displays provide full-color. High-resolution monochrome displays are generally reserved for specialty applications, which require the user to resolve very fine spatial information. Applications requiring high-resolution monochrome displays are primarily limited to applications in which high resolution monochrome imagery is captured to enable human decision making. One such application is the display of diagnostic quality medical imagery; including radiographs, computed topography, magnetic resonance and ultrasound images. Within these applications, the user is required to detect anomalies that are represented within the tonal range of the image or within the fine spatial structure of the image. An important advantage of monochrome displays is each pixel is formed from a single sub-pixel element. The fact that fewer than three subpixels are used to form a pixel in a monochrome display allows images to be formed with higher apparent resolution than can be achieved with full color displays, which is important since the cost of full color displays with similar pixel resolution is prohibitive.

It is known, however, to improve the perceived spatial resolution in a full-color display by taking advantage of the fact that the human eye integrates light over time as well as spatial extent. Therefore, full-color displays have been formed by time-sequentially displaying three or more frames of colored light. Unfortunately, for the human eye to integrate the light appropriately, both the color of the light source and the elements in the light modulator must be refreshed at very high temporal rates. Although display devices have been built having an update rate of only 180 Hz or 360 Hz, the human visual system is generally quite sensitive to temporal variations in light and therefore visible imaging artifacts (e.g., color breakup) may be present in displays having sequential red, green, and blue fields when the field rate of the visual display is even as high as 1000 Hz when displaying very fast moving, high contrast patterns or to avoid color breakup when the human eye sweeps quickly across the display device. Within these displays, color breakup happens when a saccadic eye movement occurs during which the eye-brain system fails to perceive a portion of one of the fields. Under this circumstance, the user often perceives red or green fringes or areas within image regions that are intended to be high in luminance, such as areas of white or yellow. Because color break-up is present in all existing field-sequential color displays, full-color field sequential displays have not received acceptance within application areas requiring critical viewing of monochrome images, even though they are capable of presenting high resolution monochrome imagery.

While it is generally desirable for a high resolution monochrome display to emit light that may be perceived as white within a dim environment, under certain conditions, it is known that some advantage may be gained by shifting the color of the emission away from equal energy white, which is represented by 0.33, 0.33 in CIE 1931 chromaticity coordinate space. For example, EP1209511 A1 entitled “Monochrome liquid crystal device” discusses the need to provide a color filter over the liquid crystal device to shift the color of the emission of the display device slightly towards blue. Generally, however, these monochrome displays will present information using a color that will be perceived white in a darkened environment. Generally these colors will be within a linear distance of 0.1 CIE 1931 chromaticity units from equal energy white. Therefore, within this disclosure the color white will generally refer to any light that is within 0.1 CIE 1931 chromaticity values from equal energy white.

Various flat panel display devices are also known that may emit white light. As noted earlier, it is well known to use Liquid Crystal Displays to provide high-resolution monochrome displays. Other technologies such as displays employing organic light emitting diodes (OLED) are also known.

The structure of an OLED typically comprises, in sequence, an anode, an organic electroluminescent (EL) medium, and a cathode, which are deposited upon a substrate. The organic EL medium disposed between the anode and the cathode is commonly comprised of an organic hole-transporting layer (HTL) and an organic electron-transporting layer (ETL). Holes and electrons recombine and emit light in the ETL near the interface of HTL/ETL. Tang et al., “Organic electroluminescent diodes”, Applied Physics Letters, 51, 913 (1987), and U.S. Pat. No. 4,769,292, demonstrated highly efficient OLEDs using such a layer structure. Since then, numerous OLEDs with alternative layer structures have been disclosed. For example, there are three-layer OLEDs that contain an organic light-emitting layer (LEL) between the HTL and the ETL, such as that disclosed by Adachi et al., “Electroluminescence in Organic Films with Three-Layer Structure”, Japanese Journal of Applied Physics, 27, L269 (1988), and by Tang et al., “Electroluminescence of doped organic thin films”, Journal of Applied Physics, 65, 3610 (1989). The LEL commonly includes a host material doped with a guest material wherein the layer structures are denoted as HTL/LEL/ETL. Further, there are other multi-layer OLEDs that contain a hole-injecting layer (HIL), and/or an electron-injecting layer (EIL), and/or a hole-blocking layer, and/or an electron-blocking layer in the devices. These structures have further resulted in improved device performance. The term “EL unit” may be used to describe the layers between and in electrical contact with a pair of electrodes, and will include at least one light-emitting layer, and more typically comprises, in sequence, a hole-transport layer, a light-emitting layer, and an electron-transport layer, denoted in brief as HTL/LEL/ETL. Further, it is known to employ OLEDs to form a full-color display from an array of differently colored, light emitting elements that are either arranged spatially on a single plane as discussed by U.S. Pat. No. 5,294,869 issued to Tang and Littnan, entitled “Organic electroluminescent multicolor image display device” or are composed of three stacked, individually-addressable emissive layers as has been discussed by U.S. Pat. No. 5,703,436 issued to Forrest et al., entitled “Transparent Contacts for Organic Devices”.

To appreciate the usefulness of the current invention it is also important to understand that recent advances in computer-aided image analysis have made it possible for systems to aid the user in the detection and identification of important information that may be displayed on a monochrome display. For example, within radiology, the use of computer-aided detection of possible cancerous tissue has become accepted. Systems employing these tools have been described by Wong in U.S. Pat. No. 6,477,262, issued on Nov. 5, 2002 and entitled “Computer-aided diagnosis method and system”, as well as by Tecotzky et al. in U.S. Pat. No. 6,909,795, issued on Jun. 21, 2005 and entitled, “Communicating computer-aided detection results in a standards-based medical imaging environment”. These systems typically indicate regions in the image that may be anomalous and then provide the user an indication of the location of the anomaly. The user is then left with the task of confirming or rejecting the computer-aided detection results. One method of providing these results is to render graphical overlays onto the diagnostic image and to display the image onto the monochrome display that is used for diagnosis. The user is given the task, however, of finding the monochrome graphical overlay within the rendered image. The detection of this graphical overlay is typically accomplished by creating an overlay that has a large luminance contrast when compared to the region of the image that is being highlighted.

This solution has two significant problems. First, it is not easy for a human observer to find a monochrome target against the background of a monochrome image even when the graphical overlay that serves as the target is high in contrast. It is well known that coding the target with the use of color can significantly improve a user's ability to find a target during visual search as discussed by Christ, R. E. (1990), Review and analysis of color coding research for visual displays in Select Readings in Human Factors, Venturino, M. (Ed.), Human Factors Society, Santa Monica, Calif., pp. 89-117. Specifically, this reference indicates that visual search can be more than 40 percent faster when color is used as opposed to when luminance is used to display search targets. The second problem arises from the fact that the overlay is high in contrast, which implies that the target is significantly different in luminance from the image region containing the artifact. It is well known that details are much more visible within a region when the surrounding area matches the luminance of the region than when the surrounding area has a luminance that is significantly higher or lower than the region. Therefore, the anomaly will be less visually apparent when a graphical element is placed in its vicinity, which is significantly different in luminance.

An approach that has been employed to improve the display of this graphical information in computer aided radiography is to provide two displays as is discussed by Wong in U.S. Pat. No. 6,477,262, issued on Nov. 5, 2002 and entitled “Computer-aided diagnosis method and system”, which shows the use of both a high resolution monochrome display in concert with a lower resolution color display wherein color highlights may be shown on the low resolution color display and the user is left to find the same region on the high resolution monochrome display. This approach also suffers from two problems. The first is that now two displays are required, significantly increasing the cost and footprint of the system. The second is that the user must find the same region within the images that are shown on the two displays, which requires the user to perform another relatively difficult and laborious task.

There is a need, therefore, to provide a display, which is capable of providing a high quality, high resolution monochrome image, as well as, color highlight information to direct the user's attention to important areas of the monochrome image. Such a display will be useful in a system when it is necessary to guide a user's attention (e.g., a radiologist's attention) to an important region on the monochrome image (e.g., an anomalous region determined by a computer aided detection system). It is important, however, that the addition of color, for example through the addition of colored subpixels, not interrupt the perception of the monochrome image. That is, it should not produce either visible spatial or color artifacts within the image. It is desirable that the color information be provided at a luminance that is similar to the luminance of the image portion being highlighted. While high resolution full-color displays have been made, their cost will typically be prohibitive for wide-spread applications.

### SUMMARY OF THE INVENTION

The need is met by providing a flat panel display capable of presenting high resolution monochrome images in a desired first color and highlight images in at least a desired second color different from the first color, comprising a plurality of pixels each comprised of only two individually addressable differently colored sub-pixel elements, wherein the two individually addressable differently colored sub-pixel elements emit light of the desired first color when employed together, and wherein either or both of the differently colored sub-pixel elements may be employed to emit light of the desired second color. Displays in accordance with the invention may be used to provide highlight information along with high resolution monochrome images, without the expenses associated with fabrication of high resolution full-color displays.

### BRIEF DESCRIPTION OF THE DRAWINGS

FIG. 1 a depiction of a portion of a display comprised of pixels having two individually addressable differently colored light emitting sub-pixel elements useful in practicing the present invention;

FIG. 2 a chromaticity diagram showing chromaticity coordinates of two individually addressable differently colored light emitting sub-pixel elements useful in practicing the current invention;

FIG. 3 a depiction of a portion of a display having an alternate arrangement of two individually addressable differently colored light emitting sub-pixel elements useful in practicing an alternate embodiment of the present invention;

FIG. 4 a depiction of portion of a display having an arrangement of individually addressable differently colored light emitting sub-pixel elements useful in practicing an alternate embodiment of the present invention;

FIG. 5 a depiction of portion of a display having an arrangement of individually addressable differently colored light emitting sub-pixel elements useful in practicing an alternate embodiment of the present invention;

FIG. 6 a diagram showing a longitudinal cross section of an OLED device useful in practicing the present invention;

FIG. 7 a diagram showing a longitudinal cross section of an alternate OLED device useful in practicing the present invention;

FIG. 8 a depiction of an arrangement of pixels useful in practicing an alternate embodiment of the present invention; and

FIG. 9 a depiction of a system useful in employing a display device of the present invention.

### DETAILED DESCRIPTION OF THE INVENTION

The present invention provides a flat panel display capable of presenting high resolution monochrome images in a desired first color and highlight images in at least a desired second color different from the first color, comprising a plurality of pixels each comprised of only two individually addressable differently colored sub-pixel elements. In this flat panel display the two individually addressable differently colored sub-pixel elements emit light of the desired first color when employed together. This first color is ideally white. Either or both of the differently colored sub-pixel elements may be employed to emit light of a desired second color when employed individually. The differently colored sub-pixel elements may preferably be arranged on a rectilinear grid such that the pair of differently colored sub-pixel elements form a square pixel, and a monochrome image may be displayed on a regular two-dimensional grid, which will not have any visually apparent interruptions or apparent gaps which may provide visual distraction or mask important anomalies within the content that is displayed.

It will be appreciated that several display technologies may be used to deliver a display of the present invention. Specific embodiments including organic light emitting diode technology are provided within this disclosure. However, other technologies, such as liquid crystal, plasma, field emission, electro-phoretic, electro-wetting or other display technologies employing individually addressable differentially colored sub pixel elements may also be employed to practice the present invention.

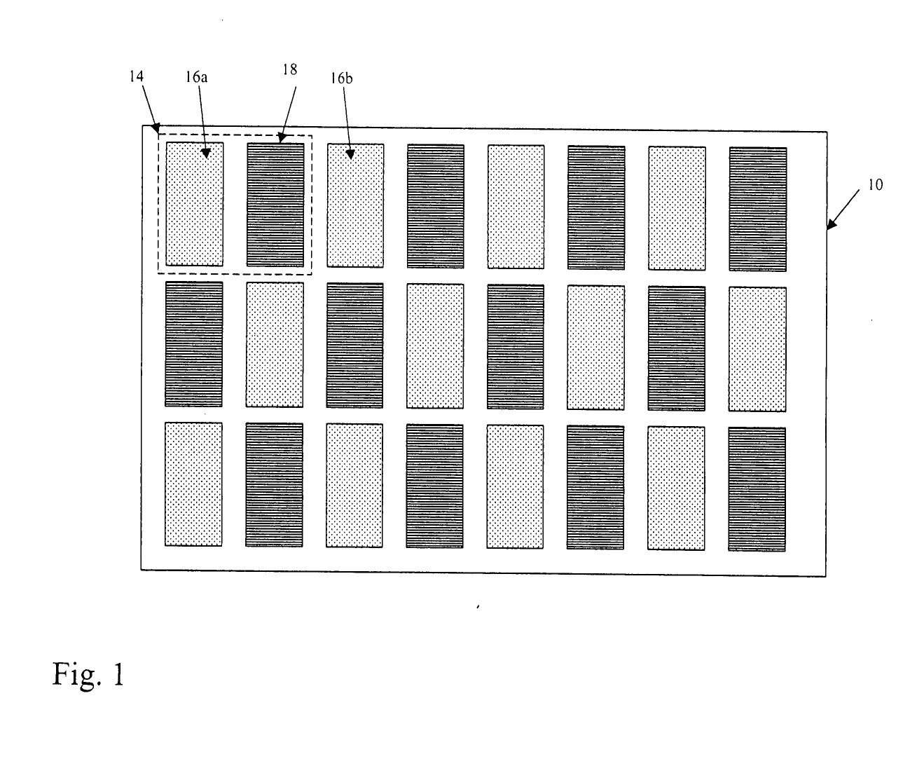

FIG. 1 shows a display of one embodiment of the present invention. As shown in FIG. 1, the display 10 is formed from an array of pixels. Each pixel 14 is formed from two individually addressable differently colored sub-pixel elements 16a (or 16b) and 18. When operated together at an appropriate luminance ratio, these two individually addressable differently colored sub-pixel elements produce a high-resolution monochrome image, which is ideally white in color. To achieve a white monochrome image the two individually addressable differently colored light emitting sub-pixel elements ideally individually produce complementary colors of light. However, when the two individually addressable differently colored sub-pixel elements are operated at any other luminance ratio (including no luminance from either subpixel), the pixel produces a second color of light, allowing highlight images to be shown.

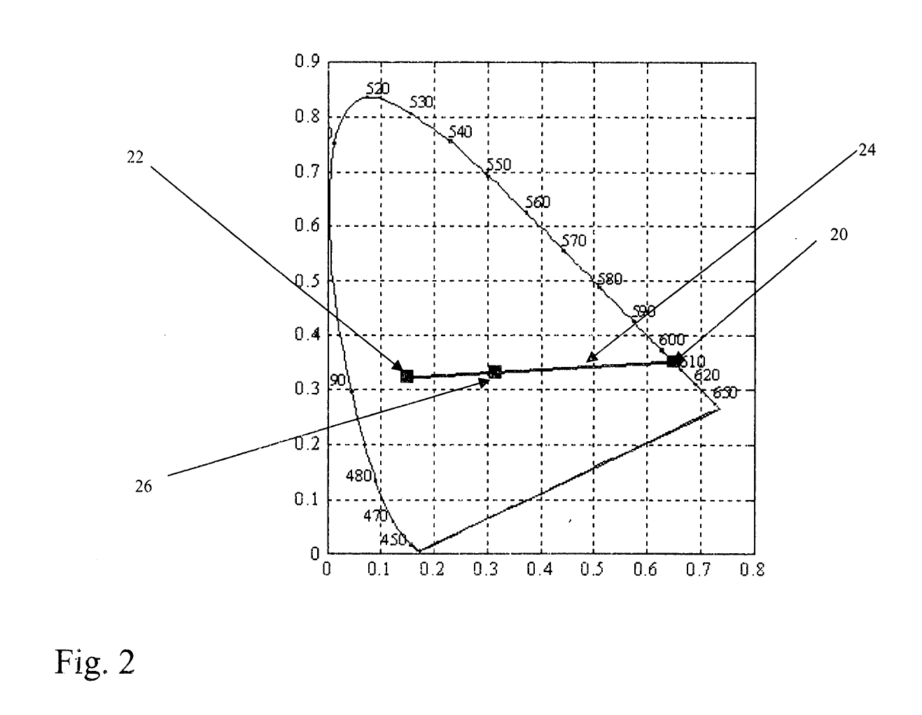

By stating that the two individually addressable differently colored sub-pixel elements produce complementary colors of light implies that when the chromaticity coordinates (20, 22) of the two individually addressable differently colored sub-pixel elements are plotted in a diagram, such as the 1931 CIE Chromaticity Diagram shown in FIG. 2, a line 24 connecting the chromaticity coordinates of the two individually addressable differently colored sub-pixel elements will intersect the desired chromaticity coordinates of the white color 26 that is desired for the display 10. Although any pairs of complementary colors may be employed, one of the individually addressable differently colored sub-pixel elements (e.g., 16 or 18) will preferably emit a primary color (e.g., red, green, or blue) while the complementary colored individually addressable differently colored sub-pixel element will emit the respective complementary color (e.g., cyan, magenta, or yellow, respectively).

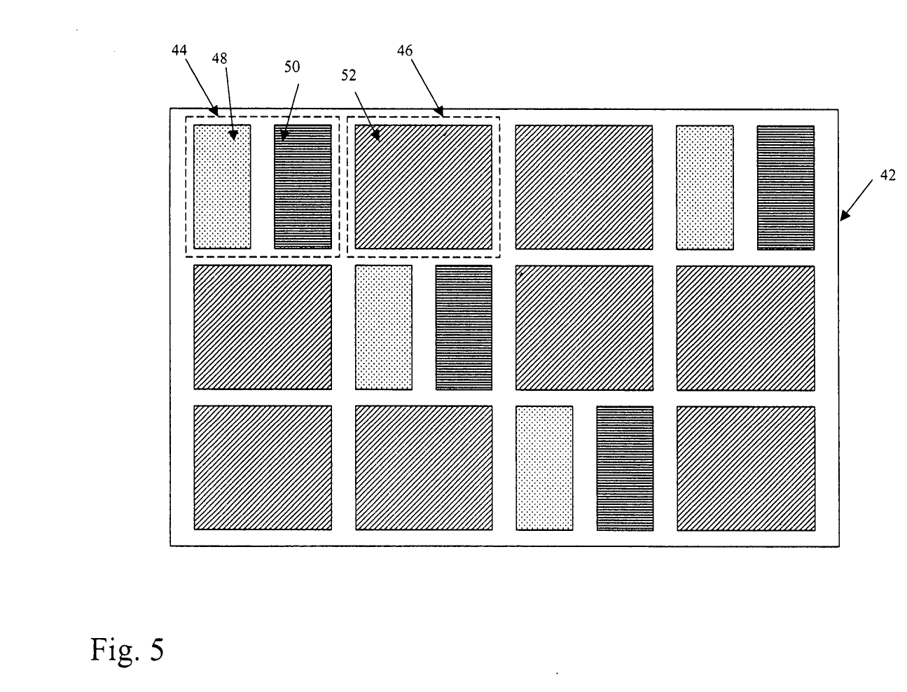

By employing the pair of individually addressable differently colored sub-pixel elements to form a white pixel 14 within the display 10, a monochrome image may be displayed with color highlighting wherein the resulting display has only two subpixels per pixel. As such, the physical pixel resolution of the display device may be improved significantly as compared to a full-color flat panel display having three or more individually addressable differently colored sub-pixel elements per pixel. However, when only one individually addressable differently colored sub-pixel elements is turned on, the display device may produce one of two highlight colors as indicated by the chromaticity coordinates 20 and 22 shown in FIG. 5. Further any color along the line connecting the chromaticity coordinates 20 and 22 may be created by altering the ratio of the luminance between the elements 16a and 18 in the first and second array, respectively.

In this particular display structure, it should be further noted that the perceived resolution of the display can be improved by dynamically allocating the boundary of any pixel. For example, if an edge finding algorithm was executed on the image that was input to the display device and a bright vertical edge was found to lie closer to the center of 16b than to 16a, the information may be presented using individually addressable differently colored sub-pixel elements 16b and 18 instead of 16a and 18. Processing input data using this or similar image processing algorithms which consider the offset between individually addressable differently colored sub-pixel elements within neighboring pixels, can effectively double the perceived resolution of the display device along the dimension of the display for which data is processed. The broad class of image processing algorithms is referred to as subpixel interpolation algorithms. An additional technique for subpixel interpolation has been discussed by Klompenhouwer et al. (2002) “Subpixel Image Scaling for Color Matrix Displays” in SID 02 Digest, pp. 176-179 and may be easily adapted for a display having two individually addressable differently colored sub-pixel elements rather than three or more.

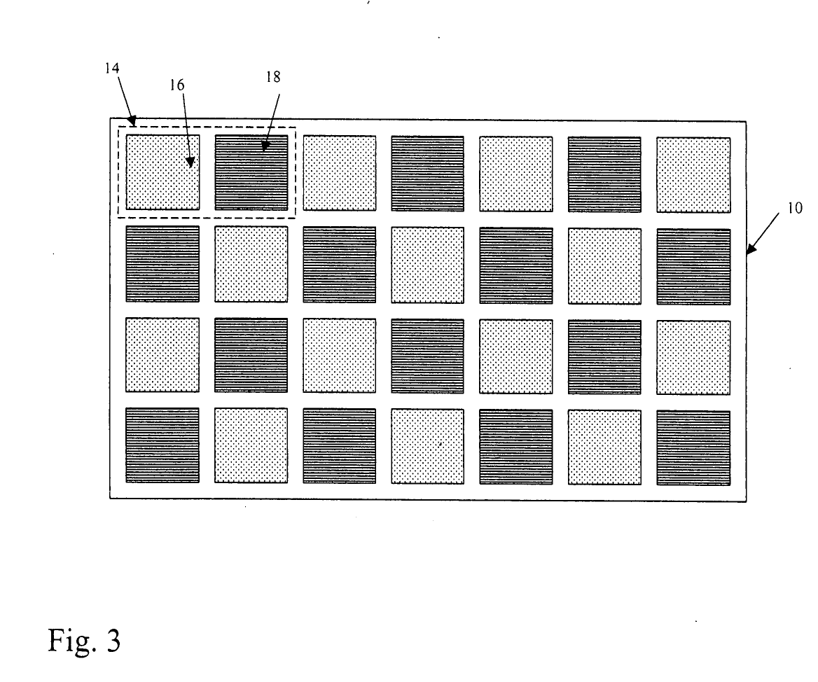

If the individually addressable differently colored sub-pixel elements 16 and 18 are square and the position of one individually addressable differently colored sub-pixel elements is offset by a half pixel 14 in successive rows, the perceived resolution can be increased significantly in both the horizontal and vertical directions, providing a display with nearly the same effective resolution as a flat panel display having pixels formed from only a single individually addressable pixel element. A portion of such a flat panel display 10 is shown in FIG. 3. Note that this display device does not have square pixels 14.

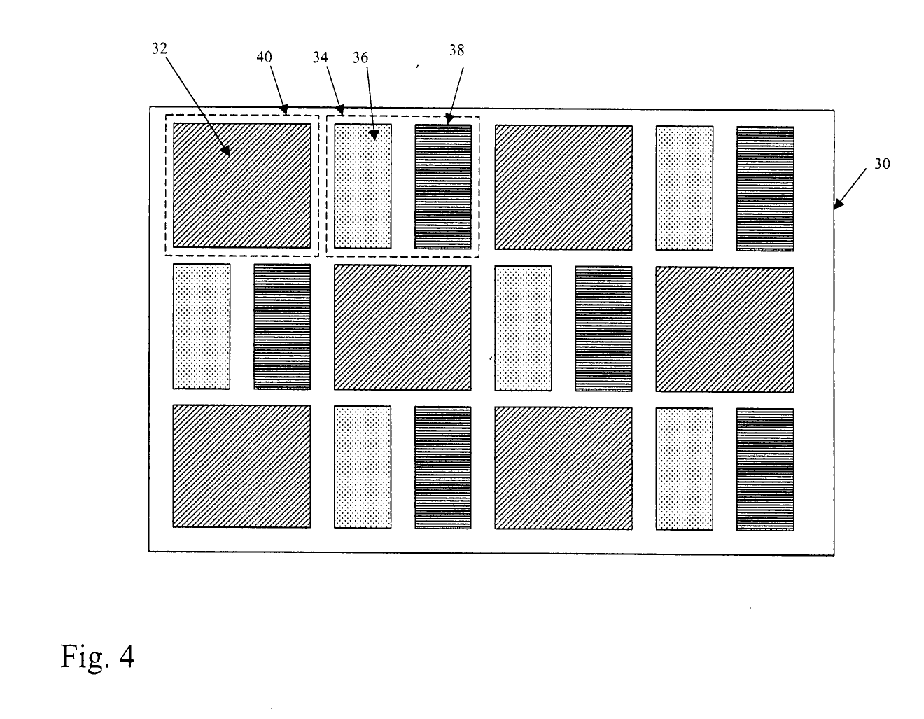

To reduce the total number of individually addressable sub-pixel elements per area, and potentially further improve the perceived resolution of the display device, pairs of individually addressable differently colored sub-pixel elements producing complementary colors may be used in conjunction with white light emitting elements. FIG. 4 shows a portion of a display 30, comprised some pixels 34 consisting of two individually addressable differently colored sub-pixel elements 36 and 38. Other pixels 40 in the display are formed from a single individually addressable pixel element 32.

Within this display device, high resolution monochrome images are formed by employing all of the individually addressable light emitting elements within both types of pixels. That is, the two individually addressable differently colored sub-pixel elements 36 and 38 are driven simultaneously to produce a color of light that is approximately the same as the color of light produced by pixel elements 32. As such, each pixel within the display 30 provides a monochrome pixel. However, since some pixels, such as 34, are composed of more than one individually addressable differently colored sub-pixel element, which can produce a different color of illumination, these individually addressable differently colored sub-pixel elements may also be employed to provide color highlights.

In this display configuration since there are as many pixels 40 that are comprised of a single individually addressable light emitting element as pixels 34 comprised of two individually addressable differently colored light emitting sub-pixel elements, the number of light emitting elements is increased to only 1.5 times the number of individually addressable light emitting elements as a purely monochrome display of equal physical pixel resolution. Further, since each of the two types of pixels 34 and 40 are arranged on the same regular two-dimensional grid, there will be no perceived distortion of the spatial information that is displayed.

To form a display of this type, it is important that both types of pixels 34 and 40 be capable of emitting light that is substantially the same color. For the color of light produced by the single individually addressable light emitting pixel element 32 to be substantially the same as the combination of the two individually addressable differently colored light emitting sub-pixel elements 36 and 38, the difference in color between the closest combination of luminance values produced by a combination of the luminance of the two individually addressable, differently colored light emitting sub-pixel elements 36 and 38 and the luminance produced by the individually addressable light emitting element 32, will be within a distance of 0.1 in the CIE x, y chromaticity space, preferably within a distance of 0.05 in the CIE x, y chromaticity space and will ideally be within a distance of 0.02 in the CIE x, y chromaticity space.

The number of light emitting elements in the display may be further reduced by reducing the number of pixels that are comprised of more than one individually addressable differently colored light emitting sub-pixel element. FIG. 5 shows a portion of a display 42 having one such arrangement, wherein there are one third as many pixels 44 that are comprised of pairs of independently addressable differently colored light emitting sub-pixel elements (48 and 50), which emit complementary colors as there are pixels 46 comprised of a single white light emitting pixel element 52.

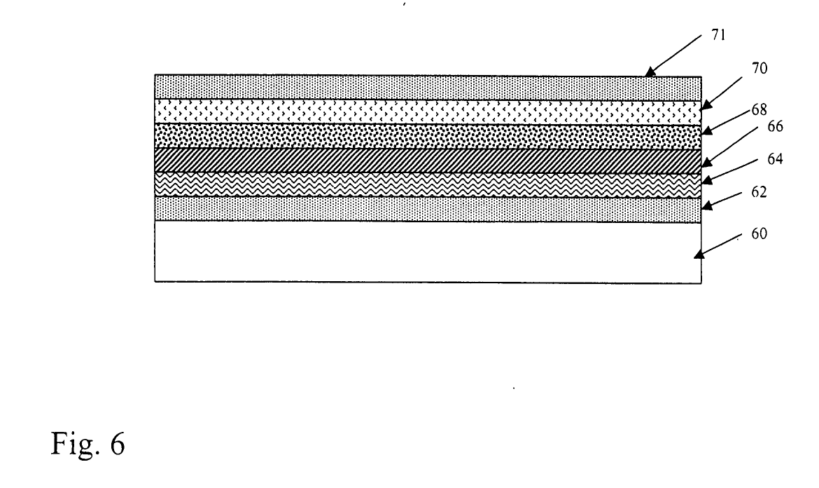

Any of the previously discussed display configurations may be formed with practically any display technology; including liquid crystal and OLED display technologies. However, one typical OLED display structure useful in practicing this invention may be formed from a two-dimensional array of OLEDs where the cross section of each OLED is shown in FIG. 6. As shown in this figure, the display is formed on a substrate 60. Each individually addressable light emitting sub-pixel element on this substrate is then formed beginning with an electrode 62. Organic material layers, including; an optional hole-injecting layer 64, a hole-transporting layer 66, a light-emitting layer 68, and an electron-transporting layer 70 are the formed over this electrode. A second electrode 71 is then formed over the organic material layers to complete the active device. Color filters or other color change media (not shown) may optionally be formed on or within this structure to tune the color of emission from the individually addressable light emitting sub-pixel element. However, different colored emission may be created from different light emitting elements by patterning of different light emitting layers 68, using optical (e.g., microcavity) effects to tune the spectrum of the emission and/or by applying color filters or other color change medium. The layers of an OLED useful in the present invention are described in detail below.

Note that the substrate 60 may alternatively be located adjacent to the cathode, or the substrate may actually constitute the anode or cathode. The organic layers between the anode and cathode are conveniently referred to as the EL unit. The total combined thickness of the EL Unit is preferably less than 500 nm. The device may be a top emitting device wherein light is emitted through a cover or a bottom emitting device that emits light through a substrate.

Substrate

OLED devices are typically provided over a supporting substrate 60. The electrode nearest the substrate is conveniently referred to as the bottom electrode. The substrate can either be light-transmissive or opaque, depending on the intended direction of light emission. The light-transmissive property is desirable for viewing the EL emission through the substrate. Transparent glass or plastic is commonly employed in such cases. For applications where the EL emission is not viewed through the bottom electrode, the transmissive characteristic of the bottom support is immaterial, and therefore can be light transmissive, light absorbing or light reflective. Substrates for use in this case include, but are not limited to, glass, plastic, semiconductor materials, silicon, ceramics, and circuit board materials. Of course in these device configurations, the remaining electrodes must be semi-transparent or transparent.

Electrodes

When EL emission is viewed through either the first 62 or the second 71 electrode, the electrode should be transparent or substantially transparent to the emission of interest. Generally, the remaining of the electrode will be reflective.

For the electrodes that serve as an anode, common transparent anode materials may be used in this invention, including indium-tin oxide (ITO), indium-zinc oxide (IZO) and tin oxide, but other metal oxides can work including, but not limited to, aluminum- or indium-doped zinc oxide, magnesium-indium oxide, and nickel-tungsten oxide. In addition to these oxides, metal nitrides, such as gallium nitride, and metal selenides, such as zinc selenide, and metal sulfides, such as zinc sulfide, can be used as the anode. For applications where EL emission is not viewed through one of the electrodes, the transmissive characteristics of the electrode are immaterial and any conductive material can be used, transparent, opaque or reflective. Example conductors for this application include, but are not limited to, gold, iridium, molybdenum, palladium, and platinum. Typical anode materials, transmissive or otherwise, have a work function of 4.1 eV or greater.

Desirable materials for the electrodes that serve as a cathode should have good film-forming properties to ensure good contact with the underlying organic layer, promote electron injection at low voltage, and have good stability. Useful cathode materials often contain a low work function metal (<4.0 eV) or metal alloy. One preferred cathode material is comprised of a Mg:Ag alloy wherein the percentage of silver is in the range of 1 to 20%, as described in U.S. Pat. No. 4,885,221. Another suitable class of cathode materials includes bi-layers comprising a thin electron-injection layer (EIL) in contact with the organic layer (e.g., ETL), which is capped with a thicker layer of a conductive metal. Here, the EIL preferably includes a low work function metal or metal salt, and if so, the thicker capping layer does not need to have a low work function. One such cathode is comprised of a thin layer of LiF followed by a thicker layer of Al as described in U.S. Pat. No. 5,677,572. Other useful cathode material sets include, but are not limited to, those disclosed in U.S. Pat. Nos. 5,059,861; 5,059,862, and 6,140,763.

When light emission is viewed through an electrode that serves as the cathode, the electrode must be transparent or semi-transparent. For such applications, metals must be thin or one must use transparent conductive oxides, or a combination of these materials. Optically transparent cathodes have been described in more detail in U.S. Pat. No. 4,885,211, U.S. Pat. No. 5,247,190, JP 3,234,963, U.S. Pat. No. 5,703,436, U.S. Pat. No. 5,608,287, U.S. Pat. No. 5,837,391, U.S. Pat. No. 5,677,572, U.S. Pat. No. 5,776,622, U.S. Pat. No. 5,776,623, U.S. Pat. No. 5,714,838, U.S. Pat. No. 5,969,474, U.S. Pat. No. 5,739,545, U.S. Pat. No. 5,981,306, U.S. Pat. No. 6,137,223, U.S. Pat. No. 6,140,763, U.S. Pat. No. 6,172,459, EP 1 076 368, and U.S. Pat. No. 6,278,236. Electrode materials are typically deposited by evaporation, sputtering, or chemical vapor deposition. When needed, patterning can be achieved through many well known methods including, but not limited to, through-mask deposition, integral shadow masking as described in U.S. Pat. No. 5,276,380 and EP 0 732 868, laser ablation, and selective chemical vapor deposition.

Hole-Injecting Layer (HIL)

It is often useful to provide a hole-injecting layer 64 between the first electrode 62 and the hole-transporting layer 66. The hole-injecting material can serve to improve the film formation property of subsequent organic layers and to facilitate injection of holes into the hole-transporting layer. Suitable materials for use in the hole-injecting layer include, but are not limited to, porphyrinic compounds as described in U.S. Pat. No. 4,720,432, and plasma-deposited fluorocarbon polymers as described in U.S. Pat. No. 6,208,075. Alternative hole-injecting materials reportedly useful in organic EL devices are described in EP 0 891 121 A1 and EP 1 029 909 A1.

Hole-Transporting Layer (HTL)

The hole-transporting layer 66 contains at least one hole-transporting compound such as an aromatic tertiary amine, where the latter is understood to be a compound containing at least one trivalent nitrogen atom that is bonded only to carbon atoms, at least one of which is a member of an aromatic ring. In one form the aromatic tertiary amine can be an arylamine, such as a monoarylamine, diarylamine, triarylamine, or a polymeric arylamine. Exemplary monomeric triarylamines are illustrated by Klupfel et al. U.S. Pat. No. 3,180,730. Other suitable triarylamines substituted with one or more vinyl radicals and/or comprising at least one active hydrogen containing group are disclosed by Brantley et al U.S. Pat. Nos. 3,567,450 and 3,658,520.

A more preferred class of aromatic tertiary amines are those which include at least two aromatic tertiary amine moieties as described in U.S. Pat. Nos. 4,720,432 and 5,061,569. The hole-transporting layer can be formed of a single or a mixture of aromatic tertiary amine compounds. Illustrative of useful aromatic tertiary amines are the following:

1,1-Bis(4-di-p-tolylaminophenyl)cyclohexane

1,1-Bis(4-di-p-tolylaminophenyl)-4-phenylcyclohexane

4,4′-Bis(diphenylamino)quadriphenyl

Bis(4-dimethylamino-2-methylphenyl)-phenylmethane

N,N,N-Tri(p-tolyl)amine

4-(di-p-tolylamino)-4′-[4(di-p-tolylamino)-styryl]stilbene

N,N,N′,N′-Tetra-p-tolyl-4-4′-diaminobiphenyl

N,N,N′,N′-Tetraphenyl-4,4′-diaminobiphenyl

N,N,N′,N′-tetra-1-naphthyl-4,4′-diaminobiphenyl

N,N,N′,N′-tetra-2-naphthyl-4,4′-diaminobiphenyl

N-Phenylcarbazole

4,4′-Bis[N-(1-naphthyl)-N-phenylamino]biphenyl

4,4′-Bis[N-(1-naphthyl)-N-(2-naphthyl)amino]biphenyl

4,4″-Bis[N-(1-naphthyl)-N-phenylamino]p-terphenyl

4,4′-Bis[N-(2-naphthyl)-N-phenylamino]biphenyl

4,4′-Bis[N-(3-acenaphthenyl)-N-phenylamino]biphenyl

1,5-Bis[N-(1-naphthyl)-N-phenylamino]naphthalene

4,4′-Bis[N-(9-anthryl)-N-phenylamino]biphenyl

4,4″-Bis[N-(1-anthryl)-N-phenylamino]-p-terphenyl

4,4′-Bis[N-(2-phenanthryl)-N-phenylamino]biphenyl

4,4′-Bis[N-(8-fluoranthenyl)-N-phenylamino]biphenyl

4,4′-Bis[N-(2-pyrenyl)-N-phenylamino]biphenyl

4,4′-Bis[N-(2-naphthacenyl)-N-phenylamino]biphenyl

4,4′-Bis[N-(2-perylenyl)-N-phenylamino]biphenyl

4,4′-Bis[N-(1-coronenyl)-N-phenylamino]biphenyl

2,6-Bis(di-p-tolylamino)naphthalene

2,6-Bis[di-(1-naphthyl)amino]naphthalene

2,6-Bis[N-(1-naphthyl)-N-(2-naphthyl)amino]naphthalene

N,N,N′,N′-Tetra(2-naphthyl)-4,4″-diamino-p-terphenyl

4,4′-Bis{N-phenyl-N-[4-(1-naphthyl)-phenyl]amino}biphenyl

4,4′-Bis[N-phenyl-N-(2-pyrenyl)amino]biphenyl

2,6-Bis[N,N-di(2-naphthyl)amine]fluorene

1,5-Bis[N-(1-naphthyl)-N-phenylamino]naphthalene

Another class of useful hole-transporting materials includes polycyclic aromatic compounds as described in EP 1 009 041. In addition, polymeric hole-transporting materials can be used such as poly(N-vinylcarbazole) (PVK), polythiophenes, polypyrrole, polyaniline, and copolymers such as poly(3,4-ethylenedioxythiophene)/poly(4-styrenesulfonate) also called PEDOT/PSS.

Light-Emitting Layer (LEL)

As more fully described in U.S. Pat. Nos. 4,769,292 and 5,935,721, the light-emitting layer (LEL) 68 will include a luminescent or fluorescent material where electroluminescence is produced as a result of electron-hole pair recombination in this region. The light-emitting layer can be comprised of a single material, but more commonly consists of a host material doped with a guest compound or compounds where light emission comes primarily from the dopant and can be of any color. The host materials in the light-emitting layer can be an electron-transporting material, as defined below, a hole-transporting material, as defined above, or another material or combination of materials that support hole-electron recombination. The dopant is usually chosen from highly fluorescent dyes, but phosphorescent compounds, e.g., transition metal complexes as described in WO 98/55561, WO 00/18851, WO 00/57676, and WO 00/70655 are also useful. Dopants are typically coated as 0.01 to 10% by weight into the host material. Polymeric materials such as polyfluorenes and polyvinylarylenes (e.g., poly(p-phenylenevinylene), PPV) can also be used as the host material. In this case, small molecule dopants can be molecularly dispersed into the polymeric host, or the dopant could be added by copolymerizing a minor constituent into the host polymer.

An important relationship for choosing a dye as a dopant is a comparison of the bandgap potential which is defined as the energy difference between the highest occupied molecular orbital and the lowest unoccupied molecular orbital of the molecule. For efficient energy transfer from the host to the dopant molecule, a necessary condition is that the band gap of the dopant is smaller than that of the host material.

Host and emitting molecules known to be of use include, but are not limited to, those disclosed in U.S. Pat. Nos. 4,768,292; 5,141,671; 5,150,006; 5,151,629; 5,405,709; 5,484,922; 5,593,788; 5,645,948; 5,683,823; 5,755,999; 5,928,802; 5,935,720; 5,935,721; and 6,020,078.

Metal complexes of 8-hydroxyquinoline (oxine) and similar derivatives constitute one class of useful host compounds capable of supporting electroluminescence. Illustrative of useful chelated oxinoid compounds are the following:

CO-1: Aluminum trisoxine [alias, tris(8-quinolinolato)aluminum(III)]

CO-2: Magnesium bisoxine [alias, bis(8-quinolinolato)magnesium(II)]

CO-3: Bis[benzo{f}-8-quinolinolato]zinc (II)

CO-4: Bis(2-methyl-8-quinolinolato)aluminum(III)-μ-oxo-bis(2-methyl-8-quinolinolato)aluminum(III)

CO-5: Indium trisoxine [alias, tris(8-quinolinolato)indium]

CO-6: Aluminum tris(5-methyloxine) [alias, tris(5-methyl-8-quinolinolato)aluminum(III)]

CO-7: Lithium oxine [alias, (8-quinolinolato)lithium(I)]

CO-8: Gallium oxine [alias, tris(8-quinolinolato)gallium(III)]

CO-9: Zirconium oxine [alias, tetra(8-quinolinolato)zirconium(IV)]

Other classes of useful host materials include, but are not limited to: derivatives of anthracene, such as 9,10-di-(2-naphthyl)anthracene and derivatives thereof, distyrylarylene derivatives as described in U.S. Pat. No. 5,121,029, and benzazole derivatives, for example, 2,2′,2″-(1,3,5-pherylene)tris[1-phenyl-1H-benzimidazole].

Useful fluorescent dopants include, but are not limited to, derivatives of anthracene, tetracene, xanthene, perylene, rubrene, coumarin, rhodamine, quinacridone, dicyanomethylenepyran compounds, thiopyran compounds, polymethine compounds, pyrilium and thiapyrilium compounds, fluorene derivatives, periflanthene derivatives and carbostyryl compounds.

It should also be noted that in devices where it is important to have multiple spectral peaks, as is often necessary to obtain a white emission or secondary color emission, multiple dopants may be used within the light emitting layer. The EL unit may additionally be formed from multi-layer OLEDs, which have multiple light emitting layers. In such a device, each of the multiple light emitting layers may contain the same dopants but may also contain different dopants within the different light emitting layers.

In one particularly interesting embodiment, the two individually addressable differently colored light emitting sub-pixel elements that emit complementary colors of light may be independently doped with one or more dopants while the single individually addressable light emitting element that forms white light emitting pixels may be formed to have a combination of the dopants that are present within the two individually addressable differently colored light emitting sub-pixel elements. This embodiment is particularly interesting since it insures that the color emission of the two individually addressable differently colored light emitting sub-pixel elements are truly complementary to the white light that is produced by the single individually addressable light emitting element that forms white light emitting pixel.

Electron-Transporting Layer (ETL)

Thin film-forming materials for use in forming the electron-transporting layer 70 of the EL unit of this invention may be metal chelated oxinoid compounds, including chelates of oxine itself (also commonly referred to as 8-quinolinol or 8-hydroxyquinoline). Such compounds help to inject and transport electrons, exhibit high levels of performance, and are readily fabricated in the form of thin films. Exemplary oxinoid compounds were listed previously.

Other electron-transporting materials include various butadiene derivatives as disclosed in U.S. Pat. No. 4,356,429 and various heterocyclic optical brighteners as described in U.S. Pat. No. 4,539,507. Benzazoles and triazines are also useful electron-transporting materials.

In some instances, layers 66 and 68 can optionally be collapsed into a single layer that serves the function of supporting both light emission and electron transport. These layers can be collapsed in both small-molecule OLED systems and in polymeric OLED systems. For example, in polymeric systems, it is common to employ a hole-transporting layer such as PEDOT-PSS with a polymeric light-emitting layer such as PPV. In this system, PPV serves the function of supporting both light emission and electron transport.

Deposition of Organic Layers

The organic materials mentioned above are suitably deposited through a vapor-phase method such as sublimation, but can be deposited from a fluid, for example, from a solvent with an optional binder to improve film formation. If the material is a polymer, solvent deposition is useful but other methods can be used, such as sputtering or thermal transfer from a donor sheet. The material to be deposited by sublimation can be vaporized from a sublimator “boat” often comprised of a tantalum material, e.g., as described in U.S. Pat. No. 6,237,529, or can be first coated onto a donor sheet and then sublimed in closer proximity to the substrate. Layers with a mixture of materials can utilize separate sublimator boats or the materials can be pre-mixed and coated from a single boat or donor sheet. Patterned deposition can be achieved using shadow masks, integral shadow masks (U.S. Pat. No. 5,294,870), spatially-defined thermal dye transfer from a donor sheet (U.S. Pat. Nos. 5,851,709 and 6,066,357) and inkjet method (U.S. Pat. No. 6,066,357).

Encapsulation

Most OLED devices are sensitive to moisture or oxygen, or both, so they are commonly sealed in an inert atmosphere such as nitrogen or argon, along with a desiccant such as alumina, bauxite, calcium sulfate, clays, silica gel, zeolites, alkaline metal oxides, alkaline earth metal oxides, sulfates, or metal halides and perchlorates. Methods for encapsulation and desiccation include, but are not limited to, those described in U.S. Pat. No. 6,226,890. In addition, barrier layers such as SiOx, Teflon, and alternating inorganic/polymeric layers are known in the art for encapsulation.

Optical Optimization

OLED devices of this invention can employ various well-known optical effects to enhance its properties if desired. This includes optimizing layer thicknesses to yield maximum light transmission, providing dielectric mirror structures, replacing reflective electrodes with light-absorbing electrodes. providing anti glare or anti-reflection coatings over the display, providing a polarizing medium over the display, or providing colored, neutral density, or color conversion filters over the display. Filters, polarizers, and anti-glare or anti-reflection coatings may be specifically provided over the cover or as part of the cover.

Tandem Structures

Although the embodiment depicted in FIG. 6 illustrates single units located between electrode pairs 62 and 71, respectively, this EL unit may be a multi-layer structure having multiple EL units operating in tandem positioned there between as disclosed in US 2003/0170491 filed by Liao and Tang and entitled “Providing an organic electroluminescent device having stacked electroluminescent units” and US 2003/0189401 filed by Kido and Hayashi and entitled “Organic electroluminescent device”. In such a tandem device, a plurality of light-emitting layers are provided between a pair of electrodes, thereby increasing the amount of light emitted at the cost of an increased driving voltage. Within these structures a connecting layer is often coated between successive layers of HIL, HTL, LEL, and ETL. Such a connecting layer may also be formed from a hole-transporting layer and an electron-transporting layer.

As noted earlier, other display technologies, including LCDs, may be used to provide a display according to one of the previously disclosed embodiments of the present invention. Within an LCD, light will typically be emitted by a backlight. The light produced by the backlight may be formed using any emissive light source, including, but not limited to, fluorescent bulbs, inorganic light emitting diodes or organic light emitting diodes. Within a LCD, this light will typically pass through a polarizer, the light will then be modulated by electrically changing the state of a liquid crystal within a cell to change the polarization of the light. The light is then passed through a second polarizing sheet, which filters out light that does not have the proper polarization to pass through this sheet. The display will then typically employ color filters over at least the liquid crystal cells that emit colored light to form two individually addressable differently colored light emitting sub-pixel elements and color filters or neutral density filters may be placed over the liquid crystal cells that are intended to transmit white light to form the single individually addressable light emitting element that forms the white light emitting pixels.

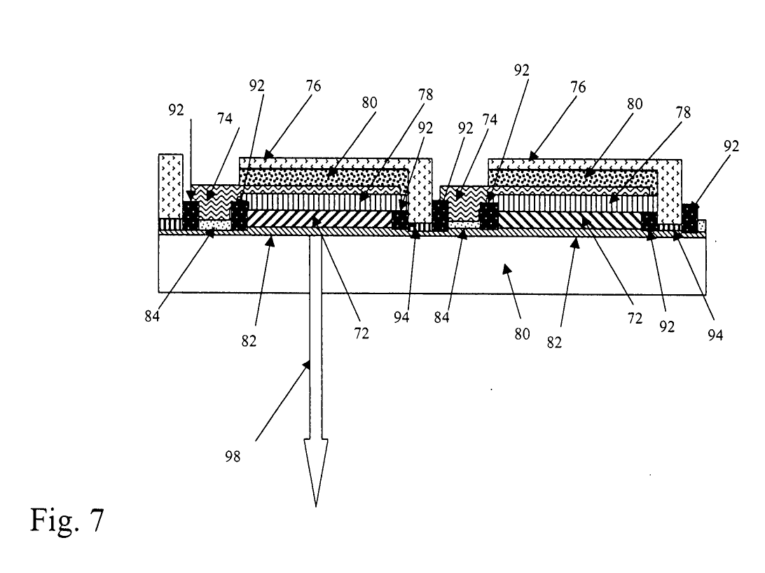

A flat panel display capable of presenting high resolution monochrome images in a desired first color and highlight images in at least a desired second color different from the first color can also be formed from an OLED display having a first array of individually addressable light emitting sub-pixel elements producing light having a first color that are formed on a first layer of a stacked display structure and a second array of individually addressable light emitting sub-pixel elements that produces light of a second color different from the first color where these light emitting elements are formed on a second layer of a stacked display structure. In such a display, the first and second arrays of light emitting sub-pixel elements are formed on a regular rectangular grid, such that the differently colored sub-pixel elements in the two layers overlap, creating stacked pixels. In one specific embodiment, one layer of such a device employing stacked sub-pixels may be comprised of white light emitting sub-pixels, while the other layer is comprised of sub-pixels that emit light of a desired highlight color. In an alternative embodiment, the two layers of sub-pixel elements may emit light of complimentary colors. A schematic cross section of a bottom-emitting, active-matrix embodiment of such a stacked layer device is shown in FIG. 7.

As shown in this figure, the active-matrix structure will typically be formed on a substrate 80. Light emission 98 will occur through this substrate. On this substrate, a drive circuitry layer 82 will be formed that contains thin-film transistors and other drive circuitry to drive the device as is known in the art. Over this drive circuitry, the first electrode 72 will be patterned. Within this bottom-emitting configuration, this first electrode will preferably be transparent. A first connector 84 for the second 74 electrode will also be formed such that it is not in contact with the first 72 and third 76 electrode. A second connector 94, used to connect the third 76 electrode to the TFT layer, will also be formed. This connector 94 and the third electrode 76 will not be in electrical contact with the first 72 or second 74 electrodes. A planarization layer 92 will be patterned to electrically isolate the first connector 84 from both the first electrode 72 and the second connector 94. The bottom EL unit 78 will be formed over the first electrode 72 in such a way that a via will be provided to allow the second 74 and third 76 electrodes to be connected to the first 84 and second 94 connector, respectively. The second electrode 74 is then formed on top of the bottom EL unit 78 and surrounding area, such that it forms an electrical connection with the first connector 84. The top EL unit 80 is then formed over the second electrode 72. Finally the third electrode 76 is formed over the top EL unit 80 in such a way that it forms an electrical connection with the second connector 94. As such, an OLED device is formed having a first array of light emitting sub-pixel elements that are formed from first electrode 72, the first EL unit 78 and second electrode 74 and a second array of light emitting sub-pixel elements located on top of the first layer which is formed from the second electrode 74, the second EL unit 80 and the third electrode 78.

The display device shown in FIG. 7 will preferably employ an active matrix of thin-film transistors (TFTs) to drive the light-emitting elements. Although it is possible to simply provide two separate TFT circuits to drive each light-emitting element within the display device, it is possible to share drive and capacitor lines for each light-emitting element, providing some simplification of the panel layout. One such circuit to achieve this has been discussed in co-pending, commonly assigned U.S. Ser. No. 11/087,522 filed Mar. 23, 2005, the disclosure of which is hereby incorporated by reference.

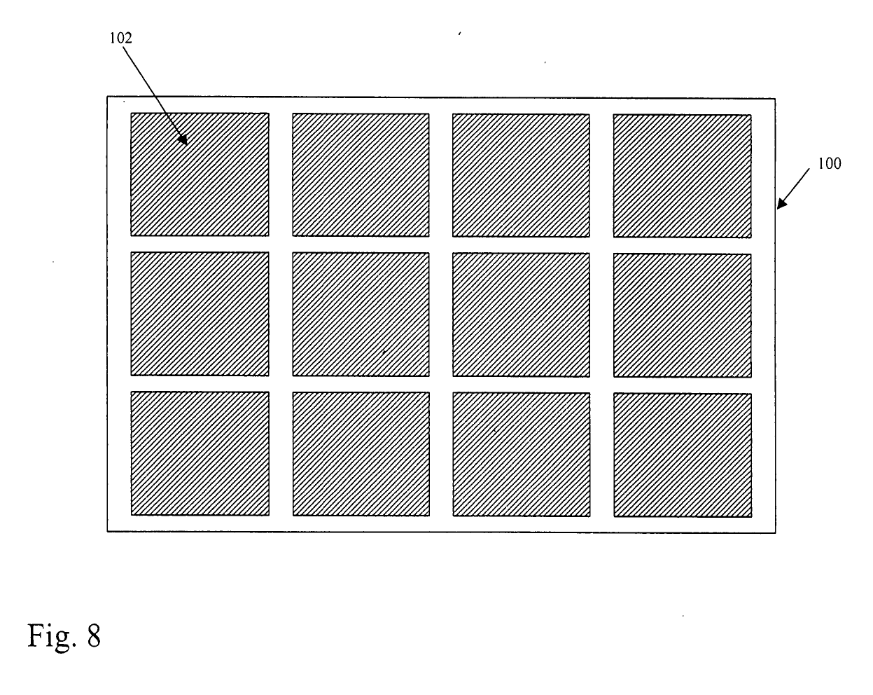

By employing a display having two layers of independently addressable light emitting sub-pixel elements, at least one of the first and second layers may comprise an array of individually addressable light emitting sub-pixel elements that emit a primary color of light. In this embodiment, the other of the first and second layers may comprise a second array of individually addressable light emitting sub-pixel elements that emits light that is complementary to the su-pixel elements within the first layer. Since the sub-pixel elements in the first layer reside on a physically separate plane from the sub-pixel elements in the second layer, independently addressable light emitting elements within the two layers can be arranged to emit within substantially the same area of the flat panel display as it is viewed by a user. This feature allows an apparently white monochrome image to be displayed on a regular two-dimensional grid without interruption or apparent gaps. The top view of one display device providing such an arrangement of light emitting elements is shown in FIG. 8. The display 100 shown in FIG. 8 is composed of an array of pixels 102. Each pixel is comprised of a first individually addressable light emitting sub-pixel element that emits either a primary or secondary color of light. The pixel also provides a second individually addressable differently colored light emitting sub-pixel elements that emits light that is the complement of the first individually addressable light emitting sub-pixel element.

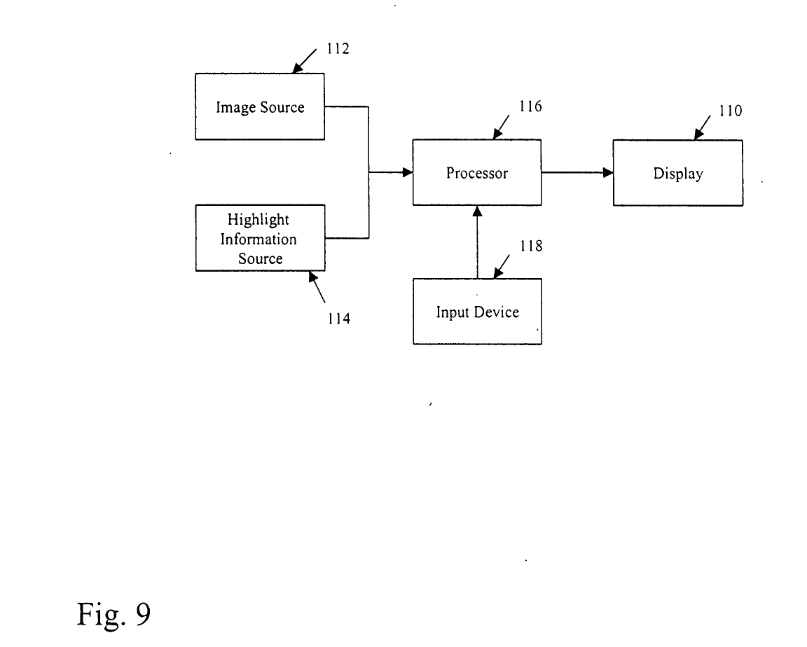

A display as described in this disclosure may be employed in any of a large number of systems. A general system including such a display is shown in FIG. 9. As shown in this figure, the system consists of a display 110 of the present invention, an image information source 112 that provides the monochrome image information, a highlight information source 114 and a processor 116 for merging the information from the two sources 112 and 114 and rendering the information to the display 110. The image information source 112 is any device capable of acquiring or storing a digital monochrome image; including a digital image capture device, an image scanner, or a storage medium. The highlight information source 114 may be any device capable of determining or storing coordinates of pixels within the monochrome image that are to be highlighted; including a processor for executing a computer aided diagnostic algorithm, a processor for determining information from ultrasound returns, or a storage device capable of storing the coordinates of highlight information that was determined using some other process, including information that was obtain from annotation by a human observer. The processor 116, is any device capable of obtaining information from the two image sources, merging them for display on the display device and rendering them to code values that are appropriate for human viewing. The system will also optionally provide an input device 118, that may be used by a human operator to instruct the processor 116 to perform any number of processing steps, including to display only the monochrome image information or only the highlight information on the display 110. This input device may be a mouse, keyboard, or any other device capable of obtaining information from the user of the system.

Such a system may be employed in any number of applications. In one preferable embodiment, the image information source 112 is a digital radiographic capture system which is employed to capture a digital radiograph of a patient. The highlight information source 114 is a processor that executes a computer aided diagnostic algorithm on the image information to determine possible medically significant abnormalities within the image data. A processor, 116, potentially the same processor as is used to execute the computer aided diagnostic algorithm, then merges the information from the two sources 112 and 114 and displays them on the display 110. The user then views the information and uses a single button on the user interface to toggle on and off the display of the highlight information, allowing him or her to quickly locate areas where the computer aided diagnostic system determined abnormalities could exist and then remove the highlight information to confirm or reject the hypothesis that an abnormality exists within the highlighted area. In addition to the highlighted image information, patient history and statistics may be displayed and any particularly relevant information may be highlighted when shown on the display.

In another potential embodiment, a continuous ultrasound image may be captured of a patient's heart. In this system, the ultrasound may provide the image information source 112, allowing the system to create a rendering of the heart. However, since these systems are also typically able to use sound feedback to determine arterial and venous blood flow, algorithms may be applied on a processor to determine areas of arterial or venous blood flow. In this case the ultrasound system also serves as a highlight information source 114. The image of the heart may then be produced as a monochrome image within a display of the current invention wherein the two individually addressable differently colored light emitting sub-pixel elements emit complementary colors (e.g., red and cyan). Areas within this image in which arterial blood flow is occurring may then be colored using individually addressable light emitting sub-pixel elements having one of the complementary colors (e.g., red). Areas within this image in which venous blood flow is occurring may then be colored using individually addressable light emitting sub-pixel elements of the complementary color (e.g., cyan). When other information, such as the rate of blood flow is known, areas of slow blood flow may be rendered using both complementary colors to create a colored region that is low in color saturation. Areas with faster blood flow may be rendered using one or both of the complementary colors to create a region that is high in color saturation. By performing a rendering in this way, the ultrasound system not only is capable of displaying a very high resolution monochrome image of the heart but of depicting important information to the user of the ultrasound in a way that it can be easily found and identified.

The invention has been described in detail with particular reference to certain preferred embodiments thereof, but it will be understood that variations and modifications can be effected within the spirit and scope of the invention.

### PARTS LIST

10 display
14 pixel
16 individually addressable light emitting sub-pixel element
18 individually addressable light emitting sub-pixel element
20 chromaticity coordinate of an individually addressable light emitting sub-pixel element
22 chromaticity coordinate of a second individually addressable light emitting sub-pixel element
24 line
26 chromaticity coordinates of the white color
30 display
32 individually addressable light emitting sub-pixel element
34 pixel
36 individually addressable light emitting sub-pixel element
38 individually addressable light emitting sub-pixel element
40 pixel
42 display
44 pixel comprised of pairs of independently addressable differently colored light emitting sub-pixel elements
46 pixel comprised of a single white light emitting element
48 independently addressable light emitting sub-pixel element
50 independently addressable light emitting sub-pixel element
52 white light emitting element
60 substrate
62 electrode
64 hole-injecting layer
66 hole-transporting layer
68 light-emitting layer
70 electron-transporting layer
71 second electrode
72 first electrode
74 second electrode
76 third electrode
78 bottom EL unit
80 top EL unit
84 first connector
90 pixel comprised of a single white light emitting element
92 planaraztion layer
94 second connector
100 display
102 pixels
110 display
112 image information source
114 highlight information source
116 processor
118 input device

1. A flat panel display capable of presenting high resolution monochrome images in a desired first color and highlight images in at least a desired second color different from the first color, comprising a plurality of pixels each comprised of only two individually addressable differently colored sub-pixel elements, wherein the two individually addressable differently colored sub-pixel elements emit light of the desired first color when employed together, and wherein either or both of the differently colored sub-pixel elements may be employed to emit light of the desired second color.

2. A display according to claim 1, wherein the first color has x and y chromaticity coordinates as defined within the CIE 1931 chromaticity diagram which are between 0.23 and 0.33.

3. A display according to claim 1, wherein the individually addressable differently colored subpixel elements individually emit light of complementary colors.

4. A display according to claim 3, wherein the complementary colors are red and cyan, green and magenta, or blue and yellow.

5. A display according to claim 1, wherein the display further comprises a signal processor that utilizes subpixel interpolation to provide higher perceived resolution.

6. A display according to claim 1, further comprising additional pixels comprised of only a single individually addressable pixel element that emits light that has x and y chromaticity coordinates as defined within the CIE 1931 chromaticity diagram have distances within 0.1 from the x and y chromaticity coordinates of the desired first color.

7. A display according to claim 6, comprising a larger number of additional pixels comprised of only a single individually addressable pixel element than pixels comprised of only two individually addressable differently colored sub-pixel elements.

8. A display according to claim 1, wherein the flat panel display is an OLED display device.

9. An OLED display according to claim 8, wherein the two individually addressable differently colored subpixel elements are comprised of different light-emitting layers including different light emitting materials.

10. The OLED display according to claim 9, further comprising additional pixels comprised of only a single individually addressable pixel element that emits light that has x and y chromaticity coordinates as defined within the CIE 1931 chromaticity diagram have distances within 0.1 from the x and y chromaticity coordinates of the desired first color.

11. The OLED display according to claim 10, wherein the single individually addressable pixel elements of the additional pixels comprise multiple light-emitting layers including the different light emitting materials of the two individually addressable differently colored subpixel elements.

12. An OLED display according to claim 8, wherein the two individually addressable differently colored subpixel elements are comprised of light-emitting layers including the same light emitting materials.

13. The OLED display according to claim 12, wherein the spectrum of the light emitted by the light-emitting layers of the two individually addressable differently colored subpixel elements has peaks in both the blue and yellow or a cyan and red portions of the visible spectrum.

14. An OLED display according to claim 8, wherein the two individually addressable differently colored subpixel elements emit differently colored light through the use of one or more color filters.

15. An OLED display according to claim 8, wherein the two individually addressable differently colored subpixel elements emit differently colored light through the use of a microcavity formed in at least one of the two individually addressable differently colored subpixel elements.

16. An OLED display according to claim 8, wherein the two individually addressable differently colored subpixel elements are stacked.

17. A display according to claim 1, wherein the flat panel display is an LCD display.

18. A system for displaying a monochrome image with different color highlight information, comprising a display device according to claim 1, an image information source, a highlight information source, and a processor.

19. The system in claim 18, wherein the highlight information source comprises a computer aided diagnostic system.

20. The system in claim 18, wherein the system is an ultrasound system and wherein the two individually addressable differently colored sub-pixel elements are employed to provide highlight information in two different colors, wherein one color of highlight information indicates arterial blood flow and the other color of highlight information indicates venous blood flow.
